(19) United States
(12) Patent Application Publication
(10) Pub. No.: US 2026/0309321 A1
(43) Pub. Date: Oct. 8, 2026

(54) LED DEVICE AND LED LIGHT FIXTURE

(71) Applicant: Shanghai Weili Advanced Electronic Technology Co., Ltd., Shanghai (CN)

(72) Inventor: Wei Cao, Shanghai (CN)

(21) Appl. No.: 19/638,391

(22) Filed: Apr. 3, 2026

(30) Foreign Application Priority Data
Apr. 3, 2025 (CN) 202510423636.5

(51) Int. Cl. F21V 29/83; F21S 6/00; F21V 3/06; F21V 5/04; F21V 7/00; F21V 7/06; F21V 23/00; F21V 29/503; F21V 29/508; F21V 29/60; F21V 29/71; F21V 31/00; F21Y 105/10; F21Y 115/10

(52) U.S. Cl. CPC F21V 29/83; F21S 6/006; F21V 3/06; F21V 5/045; F21V 7/0091; F21V 7/06; F21V 23/006; F21V 23/009; F21V 29/503; F21V 29/508; F21V 29/60; F21V 29/71; F21V 31/005; F21Y 2105/10; F21Y 2115/10

(57) ABSTRACT

The present disclosure provides an LED device and an LED light fixture. The LED device includes at least one LED component; a housing arranged on a back side of the at least one LED component; a heatsink arranged in the housing and on the back side of the at least one LED component; a cooling assembly arranged in the housing and including an air channel and an air entraining component arranged in the air channel; and an exhaust assembly including an exhaust chamber and at least one exhaust port. The exhaust chamber of one LED device is capable of being communicated with the exhaust chamber of adjacent LED device, such that hot air discharged from the exhaust chamber of one LED device can be discharged to the outside through the exhaust chamber of adjacent LED device without flowing through the heatsink in the air channel of adjacent LED device.

### CROSS-REFERENCE TO RELATED APPLICATIONS

This application claims the benefit of priority to Chinese Patent Application No. 202510423636.5, filed on Apr. 3, 2025, and entitled “LED Device and LED Light Fixture”, the entire disclosures of which are incorporated herein by reference.

### TECHNICAL FIELD

The present disclosure relates to the technical field of LED lighting, and more particularly to an LED device and an LED light fixture.

### BACKGROUND

LED lighting for photography and motion picture industries has been available for more than twenty years. LED light fixtures include flat panels that provide large amounts of light but have not been able to mimic lighting quality of HID light fixtures that use parabolic reflectors. That is because of the inherent differences in size and lumen density between the two. HID bulbs have a single powerful small arc that is much closer to a point source than any LED bulbs. The proportion between source size and reflector size largely determines how narrow a beam can be achieved. A small source allows a small reflector. Increasing the size of the reflector allows for a narrower beam.

LEDs of lower lumen density require many LEDs to be combined to have an equal lumen level as a single HID bulb. For these LEDs to form a narrow beam, they could be combined in a single large cluster which would require a single very large reflector, or they could be arranged in several small clusters with an equal number of corresponding small reflectors. Using LEDs instead of HID has the advantage of mixing different colors together to project almost any color, while HID only has one color per bulb. LEDs also have the advantage of being able to be placed in a waterproof housing, HID requires air cooling of the bulb and it has high voltages that are not very compatible with wet locations.

The biggest problem with large LED light fixtures is that LED devices near the top or near the center of the large array receive hot air that was previously ingested by adjacent LED devices, while any array of LEDs needs even cooling in order to operate correctly and with a good service life. Therefore, there is a need of an LED light fixture that is scalable to very large sizes and has even cooling throughout.

### SUMMARY OF THE DISCLOSURE

An embodiment of the present disclosure provides an LED device, which can provide good heat dissipation capability and keep uniform cooling of the LED components.

According to an aspect of the present disclosure, an LED device is provided. The LED device includes: at least one LED component; a housing arranged on a back side of the at least one LED component; a heatsink arranged in the housing and on the back side of the at least one LED component; a cooling assembly arranged in the housing and including an air channel and an air entraining component arranged in the air channel, wherein the air channel includes a first channel and a second channel extending radially outward from the first channel, the air entraining component is arranged in the first channel and configured to introduce an air towards the heatsink in an axial direction of the air channel to dissipate heat from the heatsink, and the second channel is arranged adjacent to the heatsink and configured to allow a hot air from the heatsink to flow in a radial direction of the air channel; and an exhaust assembly arranged in the housing and configured to receive the hot air from the second channel, wherein the exhaust assembly includes an exhaust chamber and at least one exhaust port, wherein the exhaust chamber surrounds the air channel and communicates with the second channel of the air channel, and the at least one exhaust port is formed on the housing and communicated with the exhaust chamber to discharge the hot air to an outside. The exhaust chamber of one LED device is capable of being communicated with the exhaust chamber of adjacent LED device, such that the hot air discharged from the exhaust chamber of one LED device can be discharged to the outside through the exhaust chamber of adjacent LED device without flowing through the heatsink in the air channel of adjacent LED device.

According to some embodiments, the at least one exhaust port is arranged at a distance from the second channel and away from the heatsink.

According to some embodiments, a diameter of the second channel gradually increases in a direction away from the first channel.

According to some embodiments, the exhaust assembly includes four exhaust ports evenly distributed around the housing.

According to some embodiments, each LED component includes: an LED PCB; an LED array arranged on the LED PCB; and an LED optical element surrounding the LED array and configured to reflect light from the LED array.

According to some embodiments, the LED optical element includes a bifurcated parabolic reflector.

According to some embodiments, each LED component further includes a TIR lens configured to focus light from the LED array.

According to some embodiments, each LED component further includes a Fresnel lens (114) configured to focus light from the LED array.

According to some embodiments, the Fresnel lens includes a light incident surface and a light emitting surface, and an exit aperture glass is arranged on a light emitting surface of the Fresnel lens, wherein the Fresnel lens covers a center part of the exit aperture glass.

According to some embodiments, an optical silicone is formed on the light emitting surface of the Fresnel lens.

According to some embodiments, a diameter of the Fresnel lens is at least equal to a diameter of the LED array.

According to some embodiments, the Fresnel lens is formed by a mold.

According to some embodiments, the LED device further includes a drive electronic device arranged in the air channel and configured to drive the at least one LED component.

According to some embodiments, the LED device further includes a waterproof container configured to accommodate the drive electronic device.

According to some embodiments, the LED device further includes an optical container configured to cover the at least one LED component, and the heatsink and the optical container form a sealed space for accommodating the at least one LED component.

According to some embodiments, each LED in the LED array has a CRI or TLCI of at least 90.

According to some embodiments, the LED array includes: a first LED sub-array; a second LED sub-array surrounding the first LED sub-array; and a third LED sub-array surrounding the second LED sub-array; wherein the first LED sub-array, the second LED sub-array and the third LED sub-array are driven separately to emit light to achieve different beam angles.

According to another aspect of the present disclosure, an LED light fixture is provided. The LED light fixture includes: a support stand; and a plurality of LED devices according to any one of preceding embodiments, wherein the plurality of LED devices are fixed to the support stand adjacent to each other. The exhaust chamber of one LED device is capable of being communicated with the exhaust chamber of adjacent LED device, such that the hot air discharged from the exhaust chamber of one LED device can be discharged to the outside through the exhaust chamber of adjacent LED device without flowing through the heatsink in the air channel of adjacent LED device.

According to another aspect of the present disclosure, an LED device is provided. The LED device includes: at least one LED component; a housing arranged on a back side of the at least one LED component; a heatsink arranged in the housing and on the back side of the at least one LED component; and a cooling assembly arranged in the housing and including an air channel and an air entraining component arranged in the air channel. The air channel includes a first channel, a second channel and a third channel. The first channel is arranged on the back side of the at least one LED component, the third channel is arranged on a front side of the at least one LED component, and the second channel is communicated with the first channel and the third channel. The heatsink is arranged in the second channel, and the air entraining component is configured to introduce an air towards the heatsink to dissipate heat from the heatsink.

According to some embodiments, the cooling assembly includes a plurality of third channels arranged around the at least one LED component.

According to some embodiments, the air entraining component introduces the air to the second channel through the first channel to dissipate heat from the heatsink, and discharges a hot air from the heatsink to an outside through the third channel.

According to some embodiments, the air entraining component introduces the air to the second channel through the third channel to dissipate heat from the heatsink, and discharges a hot air from the heatsink to an outside through the first channel.

According to some embodiments, each LED component includes: an LED PCB; an LED array arranged on the LED PCB; and an LED optical element surrounding the LED array and configured to reflect light from the LED array.

According to some embodiments, the LED optical element includes a bifurcated parabolic reflector.

According to some embodiments, each LED component further includes a TIR lens configured to focus light from the LED array.

According to some embodiments, each LED component further includes a Fresnel lens configured to focus light from the LED array.

According to some embodiments, the Fresnel lens includes a light incident surface and a light emitting surface, and an exit aperture glass is arranged on the light emitting surface of the Fresnel lens, wherein the Fresnel lens covers a center part of the exit aperture glass.

According to some embodiments, an optical silicone is formed on the light emitting surface of the Fresnel lens.

According to some embodiments, the LED array includes: a first LED sub-array; a second LED sub-array surrounding the first LED sub-array; and a third LED sub-array surrounding the second LED sub-array; wherein the first LED sub-array, the second LED sub-array and the third LED sub-array are driven separately to emit light to achieve different beam angles.

According to another aspect of the present disclosure, an LED light fixture is provided. The LED light fixture includes: a support stand; and a plurality of LED devices according to any one of preceding embodiments, wherein the plurality of LED devices are fixed to the support stand adjacent to each other.

According to the present disclosure, in the LED device, the exhaust assembly includes an exhaust chamber and at least one exhaust port. The exhaust chamber surrounds the air channel and communicates with the second channel of the air channel, and the at least one exhaust port is formed on the housing and communicated with the exhaust chamber to discharge the hot air to the outside. With this arrangement, the exhaust chamber of one LED device is communicated with the exhaust chamber of adjacent LED device, and the hot air discharged from the exhaust chamber of one LED device is discharged to the outside through the exhaust chamber of adjacent LED device without flowing through the heatsink in the air channel of adjacent LED device.

According to the present disclosure, the cooling assembly includes an air channel and an air entraining component arranged in the air channel. The air channel includes a first channel, a second channel and a third channel. The first channel is arranged on the back side of the at least one LED component, the third channel is arranged on a front side of the at least one LED component, and the second channel is communicated with the first channel and the third channel. The heatsink is arranged in the second channel, and the air entraining component is configured to introduce an air towards the heatsink to dissipate heat from the heatsink, so that the hot air can be discharged to the outside without flowing through the heatsink in the air channel of adjacent LED device.

Therefore, the LED device of the present disclosure can achieve enough lumens by assembling a plurality of LED devices together, while providing good heat dissipation capability and keep uniform cooling of the LED components.

### BRIEF DESCRIPTION OF THE DRAWINGS

The above and other aspects, features, and advantages of the present disclosure will become more apparent from the following description, taken in conjunction with the accompanying drawings, in which:

FIG. 1 illustrates a structural view of an LED device according to an embodiment of the present disclosure;

FIG. 2 illustrates a back view of the LED device in FIG. 1;

FIG. 3 illustrates a front view of the LED device in FIG. 1;

FIG. 4A and FIG. 4B illustrate a structural view of an LED device according to another embodiment of the present disclosure;

FIG. 5 illustrates a structural view of an LED component of the LED device according to an embodiment of the present disclosure;

FIG. 6 illustrates a structural view of an LED array of the LED device according to an embodiment of the present disclosure;

FIG. 7 illustrates a perspective view of an LED light fixture according to an embodiment of the present disclosure;

FIG. 8 illustrates a back view of the LED light fixture in FIG. 7;

FIG. 9 illustrates a front view of an LED light fixture according to an embodiment of the present disclosure; and

FIG. 10 illustrates a back view of the LED light fixture in FIG. 9.

### DETAILED DESCRIPTION

Hereinafter, various embodiments of the present disclosure are described with reference to the accompanying drawings. However, it should be understood that there is no intent to limit the present disclosure to the particular forms disclosed herein; rather, the present disclosure is intended to be construed to cover various modifications, equivalents, and/or alternatives of embodiments of the present disclosure. In describing the drawings, similar reference numerals may be used to designate similar elements.

In both entertainment lighting and sport lighting, having tight narrow beams is very important. The problem is how to get enough lumens in a small area and not too big of an optic, all while keeping the LEDs cooled. In large LED light fixtures, LED devices near the top or near the center of the large array receive hot air that was previously ingested by adjacent LED devices. Therefore, there is a need of an LED light fixture that is scalable to very large sizes and has even cooling throughout.

Therefore, an embodiment of the present disclosure provides an LED device. The LED device includes: at least one LED component; a housing arranged on a back side of the at least one LED component; a heatsink arranged in the housing and on the back side of the at least one LED component; a cooling assembly arranged in the housing and including an air channel and an air entraining component arranged in the air channel; and an exhaust assembly including an exhaust chamber and at least one exhaust port. The air channel includes a first channel and a second channel extending radially outward from the first channel, the air entraining component is arranged in the first channel and configured to introduce an air towards the heatsink in an axial direction of the air channel to dissipate heat from the heatsink, and the second channel is arranged adjacent to the heatsink and configured to allow a hot air from the heatsink to flow in a radial direction of the air channel. The exhaust chamber surrounds the air channel and communicates with the second channel of the air channel, and the at least one exhaust port is formed on the housing and communicated with the exhaust chamber to discharge the hot air to the outside.

When multiple LED devices are assembled together, the exhaust chamber of one LED device is communicated with the exhaust chamber of adjacent LED device, and the hot air discharged from the exhaust chamber of one LED device is discharged to the outside through the exhaust chamber of adjacent LED device without flowing through the heatsink in the air channel of adjacent LED device.

In order to make above purposes, features and effects of the present disclosure more obvious and understandable, specific embodiments of the present disclosure will be described in detail below in combination with the attached drawings.

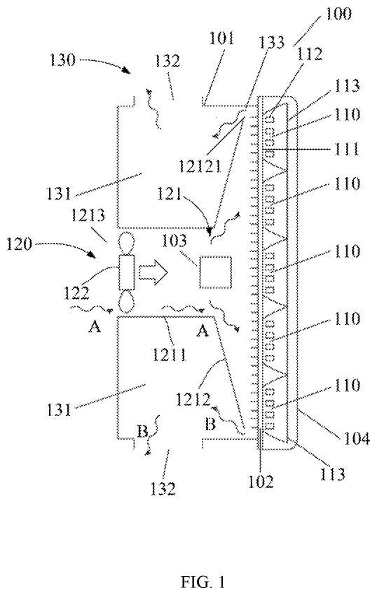

With reference to FIGS. 1 to 3, an LED device 100 includes at least one LED component 110, a cooling assembly 120 and an exhaust assembly 130. As an example, five LED components 110 are illustrated in FIG. 1. The LED components 110 are arranged in a plane and adjacent to each other. The cooling assembly 120 and the exhaust assembly 130 are arranged on a back side of the LED components 110, i.e., a side opposite to a light emission direction of the LED components 110. A housing 101 is arranged on the back side of the LED components 110 and surrounds the LED components 110, and the cooling assembly 120 and the exhaust assembly 130 are arranged in the housing 101. A heatsink 102 is arranged in the housing 101 and on the back side of the LED components 110 for dissipating heat caused by the LED components 110. For example, the heatsink 102 may be a pin fin heatsink.

The cooling assembly 120 may be arranged at a center of the back side of the LED components 110. The cooling assembly 120 includes an air channel 121 and an air entraining component 122 such as a fan arranged in the air channel 121. The air channel 121 includes a first channel 1211 and a second channel 1212 extending radially outward from the first channel 1211. The first channel 1211 and the second channel 1212 may be perpendicular to the back side of the LED components 110 and the heatsink 102. The first channel 1211 and the second channel 1212 are symmetric about their respective axes. The first channel 1211 may have a cylindrical shape, and the second channel 1212 may have a trumpet shape. The air entraining component 122 is arranged in the first channel 1211 and configured to introduce an air towards the heatsink 102 in an axial direction of the air channel 121 to dissipate heat from the heatsink 102. The second channel 1212 is arranged adjacent to the heatsink 102 and configured to allow a hot air from the heatsink 102 to flow in a radial direction of the air channel 121.

The exhaust assembly 130 surrounds the cooling assembly 120. Specifically, the exhaust assembly 130 includes an exhaust chamber 131 and at least one exhaust port 132. The exhaust chamber 131 surrounds the air channel 121 and communicates with the second channel 1212 of the air channel 121, and the exhaust port 132 is formed on the housing 101 and communicated with the exhaust chamber 131 to discharge the hot air to the outside.

More specifically, as shown in FIG. 1, the exhaust chamber 131 is formed by the housing 101, a side wall of the first channel 1211 and a side wall of the second channel 1212. The side wall of the second channel 1212 may be inclined relative to an axis of the air channel 121 at an angle of 45° to 60°, which enables the hot air to flow towards a peripheral edge 12121 of the second channel 1212 along the side wall of the second channel 1212. A gap 133 is formed between the peripheral edge 12121 of the second channel 1212 and the housing 101, and the hot air flows into the exhaust chamber 131 from the second channel 1212 through the gap 133. The gap 133 may extend around the peripheral edge 12121 of the second channel 1212 continuously or discontinuously.

When multiple LED devices 100 are assembled together, adjacent LED devices 100 are connected with each other, and the exhaust chamber 131 of one LED device 100 (for example, the LED device 100 in a center position) is directly connected and communicated with the exhaust chamber 131 of adjacent LED device 100 (for example, the LED device 100 in a peripheral position), thus the hot air discharged from the exhaust chamber 131 of one LED device 100 is discharged to the outside through the exhaust chamber 131 of adjacent LED device 100 without flowing through the heatsink 102 in the air channel 121 of adjacent LED device 100, thereby providing good heat dissipation capability and keep LED components evenly cooled.

In some embodiments, the air entraining component 122 may be a small waterproof and nearly silent fan. The air channel 121 has an entry port 1213, and entering air is drawn through the entry port 1213 by the air entraining component 122 and blown into the air channel 121 towards the heatsink 102 along an arrow A. The entering air cools the heatsink 102 and becomes hot air, and the hot air is pushed to an exhaust side of the second channel 1212 and is contained in the exhaust chamber 131 along an arrow B under a pressure difference inside and outside the LED device. The hot air then exits the exhaust chamber 131 through the exhaust port 132 arranged on all sides of the exhaust chamber 131. The hot air can exit via the nearest exhaust port 132 or/and the exhaust port 132 that is on other sides of the exhaust chamber 131. When the hot air exits via the exhaust port 132 that is on the opposite side of the exhaust chamber 131, the only major impediment to the hot air moving across the exhaust chamber 131 would be the first channel 1211 which is relatively small and thus cannot affect the flowing of the hot air.

In some embodiments, the exhaust port 132 is arranged at a distance from the second channel 1212 and away from the heatsink 102 in the axial direction of the air channel 121.

In some embodiments, a diameter of the second channel 1212 gradually increases in a direction away from the first channel 1211. That is, the second channel 1212 has a generally trumpet shape. The closer to the heatsink 102, the larger the diameter of the second channel 1212. With this arrangement, the hot air from the heatsink 102 can flow to the peripheral edge 12121 of the second channel 1212 in the radial direction of the air channel 121.

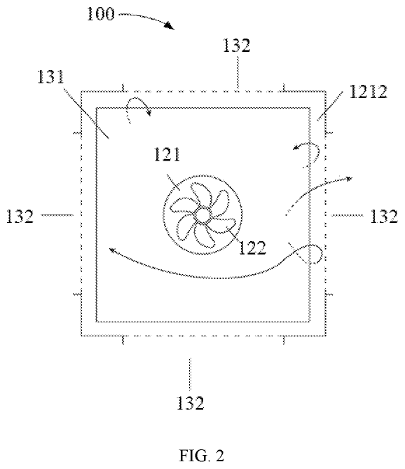

In some embodiments, the exhaust assembly 130 includes four exhaust ports 132 evenly distributed around the housing 101. As shown in FIG. 2, the LED device 100 has a square shape, and the housing 101 has a square shape. Each side of four sides of the housing 101 is provided with one exhaust port 132. In other embodiments, there are other number of exhaust ports 132, such as two, three, etc. The exhaust ports 132 may be evenly or unevenly distributed around the housing 101. The exhaust ports 132 may have the same or different size or shape.

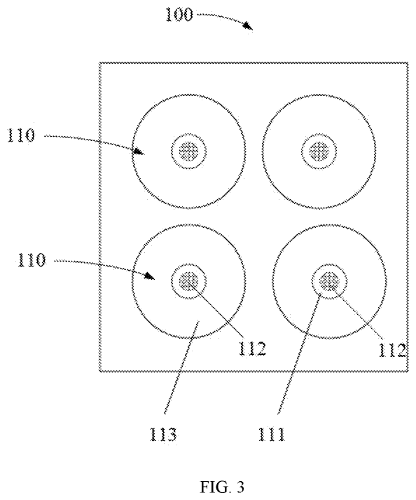

In some embodiments, as shown in FIG. 3, there are four LED components 110. In other embodiments, there are other number of LED components 110, such as two, three, five, six, etc. Each LED component 110 may be configured to emit light of the same or different color.

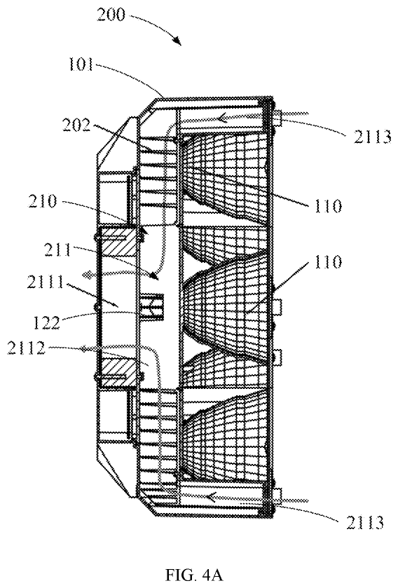

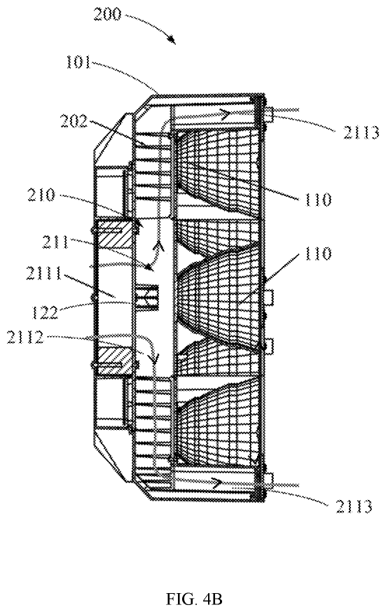

FIGS. 4A and 4B illustrate a structural view of an LED device 200 according to another embodiment of the present disclosure. As shown in FIGS. 4A and 4B, the LED device 200 includes LED components 110 and a cooling assembly 210. The LED components 110 are arranged in a plane and adjacent to each other. The cooling assembly 210 is arranged on a back side of the LED components 110, i.e., a side opposite to a light emission direction of the LED components 110. A housing 101 is arranged on the back side of the LED components 110 and surrounds the LED components 110, and the cooling assembly 210 is arranged in the housing 101. The cooling assembly 210 includes an air channel 211 and an air entraining component 122 arranged in the air channel 211. The air channel 211 includes a first channel 2111, a second channel 2112 and a third channel 2113. The first channel 2111 is arranged on the back side of the LED components 110, and the third channel 2113 is arranged on a front side of the LED components 110. The first channel 2111 and the third channel 2113 are communicated with an outside, and the second channel 2112 is communicated with the first channel 2111 and the third channel 2113. A heatsink 202 is arranged in the second channel 2112, and the air entraining component 122 may be a fan, such as a small waterproof and nearly silent fan, arranged in the first channel 2111 or the third channel 2113. The air entraining component 122 is configured to introduce an air towards the heatsink 202 to dissipate heat from the heatsink 202. For example, the heatsink 202 may be a pin fin heatsink. The first channel 2111, the second channel 2112 and the third channel 2113 are symmetrical around their respective axes. The first channel 2111, the second channel 2112 and the third channel 2113 may have a cylindrical shape. The first channel 2111 and the third channel 2113 may be perpendicular to the back side of the LED components 110 and the heatsink 202.

In some embodiments, the cooling assembly 210 includes a plurality of third channels 2113 arranged around the LED components 110.

In some embodiments, as shown in FIG. 4A, the air entraining component 122 introduces the air from the outside to the second channel 2112 through the third channel 2113 to dissipate the heat from the heatsink 202, and discharges a hot air from the heatsink 202 to the outside through the first channel 2111. That is to say, the air is introduced to the second channel 2112 through the third channel 2113 from the front side of the LED components 110, exchanges heat with the heatsink 202 in the second channel 2112, and a hot air generated by heat exchange is discharged to the outside through the first channel 2111 from the back side of the LED components 110. With this arrangement, the hot air can be discharged to the outside without flowing through the heatsink in the air channel of adjacent LED device.

In some embodiments, as shown in FIG. 4B, the air entraining component 122 introduces the air from the outside to the second channel 2112 through the first channel 2111 to dissipate the heat from the heatsink 202, and discharges a hot air from the heatsink 202 to the outside through the third channel 2113. That is to say, the air is introduced to the second channel 2112 through the first channel 2111 from the back side of the LED components 110, exchanges heat with the heatsink 202 in the second channel 2112, and a hot air generated by heat exchange is discharged to the outside through the third channel 2113 from the front side of the LED components 110. With this arrangement, the hot air can be discharged to the outside without flowing through the heatsink in the air channel of adjacent LED device.

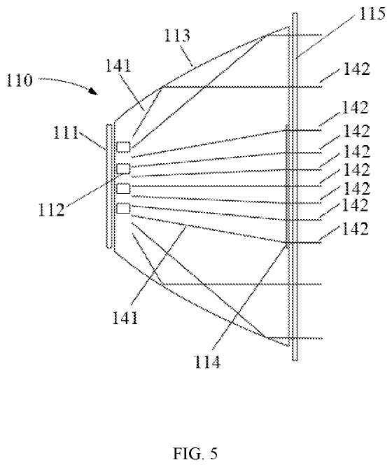

In some embodiments, with reference to FIG. 5, each LED component 110 includes an LED PCB 111, an LED array 112 and an LED optical element 113. The LED array 112 is arranged on the LED PCB 111. The LED optical element 113 surrounds the LED array 112 and is configured to reflect light from the LED array 112.

In some embodiments, the LED optical element 113 includes a bifurcated parabolic reflector. The bifurcated parabolic reflector can reflect light from the LED array 112 towards a center of a beam.

In some embodiments, the LED component 110 further includes a Fresnel lens 114 configured to focus light from the LED array 112. In other embodiments, the LED component 110 further includes a TIR lens configured to focus light from the LED array.

In some embodiments, the Fresnel lens 114 includes a light incident surface and a light emitting surface. An exit aperture glass 115 is arranged on the light emitting surface of the Fresnel lens 114, and the Fresnel lens 114 covers a center part of the exit aperture glass 115.

In some embodiments, an optical silicone is formed on the light emitting surface of the Fresnel lens 114 to make the Fresnel lens 114 directly adhere to the exit aperture glass 115. The optical silicone can minimize air-to-solid/solid-to-air optical exchange losses.

In some embodiments, a diameter of the Fresnel lens 114 is at least equal to a diameter of the LED array.

In some embodiments, the Fresnel lens 114 is formed by a mold.

Still referring to FIG. 5, emitting light 141 from the LED array 112 is reflected by the LED optical element 113 and turns to go parallel towards the center of the beam. The Fresnel lens 114 covers part of the center of the exit aperture glass 115, and emitting light 141 that comes directly from the LED array 112, are slightly redirected parallel towards the center of the beam by the Fresnel lens 114 and turned to parallel light 142. The Fresnel lens 114 allows most reflected light to transmit through the exit aperture glass 115, and the light coming directly from the LED array 112 nearer the center of the beam to be focused more precisely on the center of the beam, which can tighten the beam angle without increasing the size or length of the LED optical element 113.

The LED optical element 113 could be a lens or a reflector. The lens can focus a slightly tighter beam but has a slightly lower efficiency compared to the reflector. The reflector can make a tight beam but to do so requires the length and size of the reflector to grow to an unmanageably big size. The LED device harnesses some of the undirected light that doesn't bounce off a normal sized reflector, and directs that light to a tight center beam pattern using the Fresnel lens 114. The Fresnel lens 114 does not affect the light that is properly reflected by the LED optical element 113, as the Fresnel lens 114 is not in the light path of the reflected light, it only redirects light coming directly from the LED array 112 nearer the center of the exit aperture glass 115. A diameter of the Fresnel lens 114 is at least equal to a diameter of the LED array 112. There is a small amount of light that will exit just inside the perimeter of the aperture that can't be redirected because it is also in the exit light path of properly reflected light. The Fresnel lens 114 may be formed by a mold, and the optical silicone is formed to make the Fresnel lens directly adhere to the exit aperture glass. This would reduce transmission losses as well as minimize other mechanical changes. Thus, the LED device can tighten a beam produced by an average sized reflector by 5 degrees, adding almost 20% to the center beam brightness, and at a loss of only a couple percent in total efficiency.

In some embodiments, the LED device 100 further includes a drive electronic device 103 arranged in the second channel 1212 of the air channel 121 and configured to drive the LED components 110. The drive electronic device 103 can drive the LED components 110 to emit light simultaneously or individually.

In some embodiments, the LED device 100 further includes a waterproof container configured to accommodate the drive electronic device 103.

In some embodiments, the LED device 100 further includes an optical container 104 configured to cover the LED components 110. The optical container 104 may be made of a transparent plastic. The heatsink 102 and the optical container 104 form a sealed space for accommodating the LED component 110. Specifically, a front side of the heatsink 102, the LED PCB 111, the LED array 112, the LED optical element 113 and the optical container 104 combine and are sealed together to make an optical portion of the LED device 100 waterproof. Water can penetrate the air entraining component 122, the air channel 121, a back side of the heatsink 102, and the exhaust chamber 131 with no harm to the optical portion of the LED device 100.

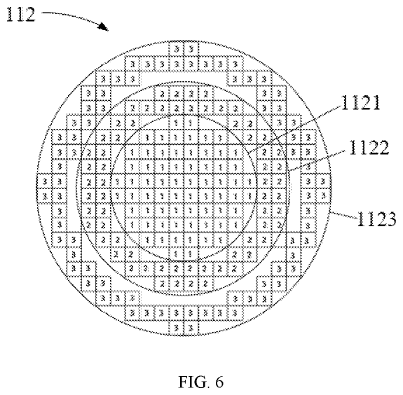

In some embodiments, as shown in FIG. 6, each square represents an LED. The LED array 112 includes a first LED sub-array 1121, a second LED sub-array 1122 and a third LED sub-array 1123. The first LED sub-array 1121 includes a plurality of first LEDs 1, the second LED sub-array 1122 includes a plurality of second LEDs 2, and the third LED sub-array 1123 includes a plurality of third LEDs 3. The second LED sub-array 1122 surrounds the first LED sub-array 1121, and the third LED sub-array 1123 surrounds the second LED sub-array 1122. The first LED sub-array 1121, the second LED sub-array 1122 and the third LED sub-array 1123 are driven separately to emit light to achieve different beam angles. The first LED sub-array 1121, the second LED sub-array 1122 and the third LED sub-array 1123 can be made of several channels of different colored LEDs, white, warm white, red, green, blue, lime, amber, purple, red-orange, royal blue, or any possible visible color. These channels can be cross faded or dimmed so that when multiple channels are powered, they combine to produce any visible color or saturation that is needed.

If only the LEDs in the first LED sub-array 1121 are powered, a narrowest beam will be formed. If the LEDs in the first LED sub-array 1121 and the LEDs in the second LED sub-array 1122 surrounding the first LED sub-array 1121 are powered, a slightly wider beam will be formed. If the LEDs in the first LED sub-array 1121, the LEDs in the second LED sub-array 1122 surrounding the first LED sub-array 1121, and the LEDs in the third LED sub-array 1123 surrounding the second LED sub-array 1122 are powered, a widest beam will be formed. It may be necessary to power multiple LED arrays at different levels to achieve different beam angles.

The LEDs in LED array could be one color or a wide variety of colors that could be controlled by multiple channels to produce virtually any visible color. The focusing elements, either the LED optical element 113 or the Fresnel lens 114, could then project this light as tight a beam as possible.

In some embodiments, the LED device may include four LED components 110. This would keep each LED component's optics or reflectors shorter and smaller. The LED device would be thinner, and lighter in weight. These LED arrays would be as small as possible to make a tight beam. Additional LEDs could be placed around the tighter LED formation that would be controlled separately to allow an electronically controlled beam angle. By powering the center LEDs at a lower power and powering up the perimeter LEDs, the beam could be widened in a solid state way. No moving parts or additional lensing, diffusion or losses required. The larger the array size, the wider the beam angle, the smaller the array size, the tighter the beam angle. Ideally, white LEDs used in these arrays would have a CRI or TLCI of a minimum of 90, as HID bulbs are closer to 60. Ideally colored LEDs would have enough variety to combine to produce virtually any visible color. LEDs would also have a much lower flicker level than HID.

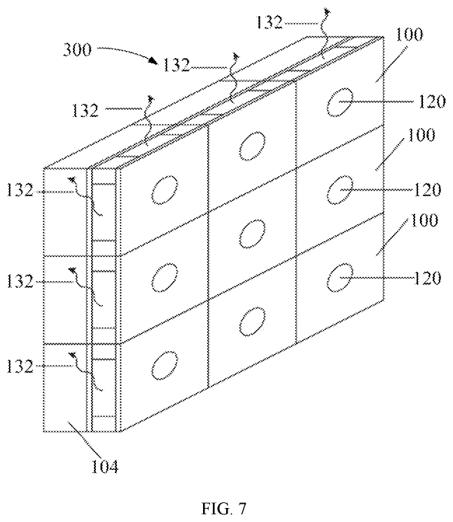

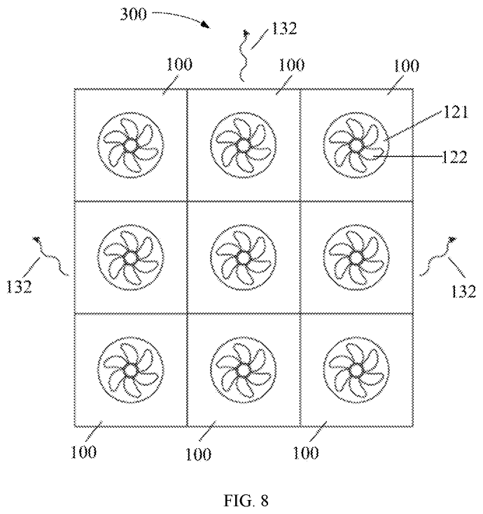

According to another aspect of the present disclosure, as shown in FIGS. 7 and 8, an LED light fixture 300 includes a support stand (not shown) and a plurality of LED devices 100. The LED devices 100 are fixed to the support stand adjacent to each other. In some embodiments, the LED light fixture 300 is used as an entertainment light fixture.

In some embodiments, nine LED devices 100 are illustrated for simplicity and clarity, but any number, such as 49, 64, or more, could be used, and the array shape doesn't have to be square, it could be rectangular in shape. The LED devices 100 don't have to be square, and they could have six sides or any number.

The exhaust chamber 131 of one LED device 100 is communicated with the exhaust chamber 131 of adjacent LED device 100, and the hot air discharged from the exhaust chamber 131 of one LED device 100 is discharged to the outside through the exhaust chamber 131 of adjacent LED device 100 without flowing through the heatsink 102 in the second channel 1212 of the air channel 121 of adjacent LED device 100.

If multiple LED devices 100 are assembled vertically, the exhaust ports on the bottom side of the LED devices 100 of the bottom row could be blocked, requiring the hot air to be shared with the remaining exhaust ports on the other three sides due to pressure difference between the LED devices 100 and the outside. This would keep the heat air from possibly being re-ingested by the fan due to convection. Air is drawn into the nine fans axially, with hot air being emitted from top and left and right sides radially. The fans in multiple LED devices 100 may be rotated in the same direction and at the same speed. In some embodiment, the rotation speed of the fan in the LED device 100 in the center of the LED light fixture 300 is greater than that of the fan in the LED device 100 in the peripheral of the LED light fixture 300.

According to the embodiments of the present disclosure, the LED devices would intake air from the backside axially and expel the heated exhaust air to the sides radially. The air intake would be driven in each LED device by the fan. The fan would blow on the back of the waterproof chamber that houses the LED arrays, lenses or reflectors. The air would cool those components. Multiple LED devices could be connected side by side, and above and below each other as a grid to form an entertainment light fixture. Each LED device would be able to take in cool fresh air from the back and expel their heated air radially or into their neighbors' exhaust chamber. Ideally the shared exhaust chambers would be large enough to accommodate several series of adjacent devices exhaust, including what they generate themselves, the heated air eventually being expelled radially by the outermost devices due to pressure difference between the LED devices and the outside.

Therefore, the LED device of the present disclosure can achieve enough lumens by assembling a plurality of LED devices together, while providing good heat dissipation capability and keep uniform cooling of the LED components.

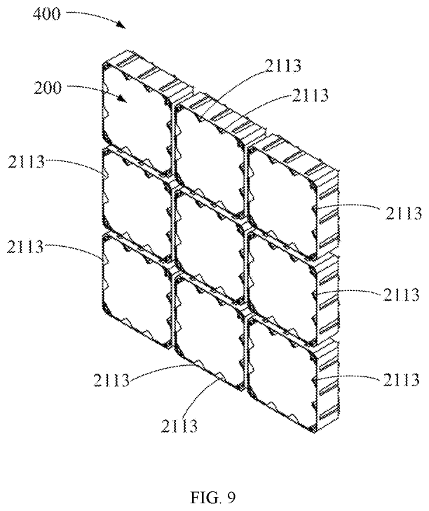

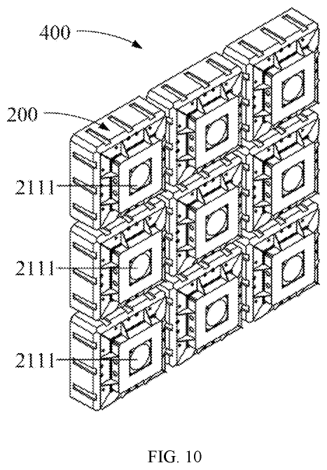

According to another aspect of the present disclosure, as shown in FIGS. 9 and 10, an LED light fixture 400 includes a support stand (not shown) and a plurality of LED devices 200. The LED devices 200 are fixed to the support stand adjacent to each other. The air is introduced to the second channel 2112 through the third channel 2113 from the front side of the LED components 110, exchanges heat with the heatsink 202 in the second channel 2112, and a hot air generated by heat exchange is discharged to the outside through the first channel 2111 from the back side of the LED components 110, or the air is introduced to the second channel 2112 through the first channel 2111 from the back side of the LED components 110, exchanges heat with the heatsink 202 in the second channel 2112, and a hot air generated by heat exchange is discharged to the outside through the third channel 2113 from the front side of the LED components 110. With this arrangement, the hot air can be discharged to the outside without flowing through the heatsink in the air channel of adjacent LED device.

It should be noted that the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. An LED device, comprising:
at least one LED component;
a housing arranged on a back side of the at least one LED component;
a heatsink arranged in the housing and on the back side of the at least one LED component;
a cooling assembly arranged in the housing and comprising an air channel and an air entraining component arranged in the air channel, wherein the air channel comprises a first channel and a second channel extending radially outward from the first channel, the air entraining component is arranged in the first channel and configured to introduce an air towards the heatsink in an axial direction of the air channel to dissipate heat from the heatsink, and the second channel is arranged adjacent to the heatsink and configured to allow a hot air from the heatsink to flow in a radial direction of the air channel; and
an exhaust assembly arranged in the housing and configured to receive the hot air from the second channel, wherein the exhaust assembly comprises an exhaust chamber and at least one exhaust port, wherein the exhaust chamber surrounds the air channel and communicates with the second channel of the air channel, and the at least one exhaust port is formed on the housing and communicated with the exhaust chamber to discharge the hot air to an outside;
wherein the exhaust chamber of one LED device is capable of being communicated with the exhaust chamber of adjacent LED device, such that the hot air discharged from the exhaust chamber of one LED device can be discharged to the outside through the exhaust chamber of adjacent LED device without flowing through the heatsink in the air channel of adjacent LED device.

2. The LED device according to claim 1, wherein the at least one exhaust port is arranged at a distance from the second channel and away from the heatsink.

3. The LED device according to claim 1, wherein a diameter of the second channel gradually increases in a direction away from the first channel.

4. The LED device according to claim 1, wherein the exhaust assembly comprises four exhaust ports evenly distributed around the housing.

5. The LED device according to claim 1, wherein each LED component comprises:
an LED PCB;
an LED array arranged on the LED PCB; and
an LED optical element surrounding the LED array and configured to reflect light from the LED array.

6. The LED device according to claim 5, wherein the LED optical element comprises a bifurcated parabolic reflector.

7. The LED device according to claim 5, wherein each LED component further comprises a TIR lens configured to focus light from the LED array.

8. The LED device according to claim 5, wherein each LED component further comprises a Fresnel lens configured to focus light from the LED array.

9. The LED device according to claim 8, wherein the Fresnel lens comprises a light incident surface and a light emitting surface, and an exit aperture glass is arranged on the light emitting surface of the Fresnel lens, wherein the Fresnel lens covers a center part of the exit aperture glass.

10. The LED device according to claim 9, wherein an optical silicone is formed on the light emitting surface of the Fresnel lens.

11. The LED device according to claim 8, wherein a diameter of the Fresnel lens is at least equal to a diameter of the LED array.

12. The LED device according to claim 8, wherein the Fresnel lens is formed by a mold.

13. The LED device according to claim 5, wherein the LED device further comprises a drive electronic device arranged in the air channel and configured to drive the at least one LED component.

14. The LED device according to claim 13, wherein the LED device further comprises a waterproof container configured to accommodate the drive electronic device.

15. The LED device according to claim 5, wherein the LED device further comprises an optical container configured to cover the at least one LED component, and the heatsink and the optical container form a sealed space for accommodating the at least one LED component.

16. The LED device according to claim 5, wherein each LED in the LED array has a CRI or TLCI of at least 90.

17. The LED device according to claim 5, wherein the LED array comprises:
a first LED sub-array;
a second LED sub-array surrounding the first LED sub-array; and
a third LED sub-array surrounding the second LED sub-array;
wherein the first LED sub-array, the second LED sub-array and the third LED sub-array are driven separately to emit light to achieve different beam angles.

18. An LED light fixture, comprising:
a support stand; and
a plurality of LED devices according to claim 1, wherein the plurality of LED devices are fixed to the support stand adjacent to each other;
wherein the exhaust chamber of one LED device is capable of being communicated with the exhaust chamber of adjacent LED device, such that the hot air discharged from the exhaust chamber of one LED device can be discharged to the outside through the exhaust chamber of adjacent LED device without flowing through the heatsink in the air channel of adjacent LED device.
